(19) United States
(12) Patent Application Publication
(10) Pub. No.: US 2026/0302923 A1
(43) Pub. Date: Oct. 1, 2026

(54) SEMICONDUCTOR DEVICE, ISOLATED DC-DC CONVERTER, AC-DC CONVERTER AND VEHICLE

(71) Applicant: ROHM CO., LTD., Kyoto (JP)

(72) Inventor: Yoshinori SATO, Kyoto (JP)

(21) Appl. No.: 19/572,499

(22) Filed: Mar. 19, 2026

(30) Foreign Application Priority Data
Mar. 26, 2025 (JP) 2025-051585

(51) Int. Cl. H02M 1/08; B60R 16/033; H02M 3/335; H02M 7/217; H03K 7/08; H03K 17/16

(52) U.S. Cl. CPC H02M 1/08; B60R 16/033; H02M 3/33515; H02M 7/217; H03K 7/08; H03K 17/162

(57) ABSTRACT

A semiconductor device includes: a first external terminal configured such that an input voltage is capable of being applied to an external resistor, and the first external terminal is connectable to the external resistor; a first MOS transistor of an N-channel configured such that a drain is connected to the first external terminal, and the drain and a gate are short-circuited; a first resistor configured to be connected to a source of the first MOS transistor; a constant current source; a second MOS transistor of an N-channel configured such that a drain is connected to the constant current source, and the drain and a gate are short-circuited; a second resistor configured to be connected to a source of the second MOS transistor; and a comparator configured such that a drain voltage of the first MOS transistor and a drain voltage of the second MOS transistor are input.

### BACKGROUND OF THE INVENTION

The present application is based on Patent Application No. 2025-051585 filed in Japan on Mar. 26, 2025.

### FIELD OF THE INVENTION

The present disclosure relates to semiconductor devices.

### DESCRIPTION OF RELATED ART

Conventionally, a control circuit used in an AC-DC converter or an isolated DC-DC converter has been known (for example, Japanese Unexamined Patent Application Publication No. 2016-146696).

In a control circuit, for example, it is required to detect an input voltage to stop the control circuit, for example, when the input voltage is lower than a specified value, that is, when a so-called brownout occurs. The detection of the input voltage is also used to optimize IC (integrated circuit) characteristics according to the input voltage.

### DESCRIPTION OF THE DRAWINGS

FIG. 1 is a diagram showing the configuration of an isolated DC-DC converter according to an illustrative embodiment of the present disclosure;

FIG. 2A is a diagram showing an example of the internal configuration of a semiconductor device;

FIG. 2B is a diagram showing another example of the internal configuration of the semiconductor device;

FIG. 2C is a waveform diagram for illustrating the sampling timing of a sample and hold circuit;

FIG. 3 is a diagram showing an example of the configuration of a current control circuit;

FIG. 4 is a timing chart showing an example of the operation of the semiconductor device;

FIG. 5 is a diagram showing a configuration related to input voltage detection in a first embodiment;

FIG. 6A is a timing chart related to input voltage detection timing control;

FIG. 6B is a timing chart related to timing control performed by a timing control unit;

FIG. 7 is a diagram showing a configuration related to input voltage detection in a second embodiment;

FIG. 8 is a diagram showing a configuration related to input voltage detection in a third embodiment;

FIG. 9 is a diagram showing a configuration related to input voltage detection in a fourth embodiment;

FIG. 10 is a diagram showing a configuration related to input voltage detection in a fifth embodiment;

FIG. 11 is an example of a plan view when viewed from above the semiconductor device;

FIG. 12 is a diagram showing an example of the configuration of an AC-DC converter; and

FIG. 13 is an external view showing an example of the configuration of a vehicle.

### DESCRIPTION OF THE PREFERRED EMBODIMENTS

An illustrative embodiment of the present disclosure will be described below with reference to drawings.

### <Isolated DC-DC Converter>

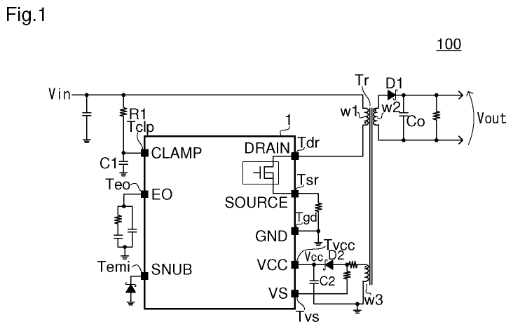

FIG. 1 is a diagram showing the configuration of an isolated DC-DC converter 100 according to the illustrative embodiment of the present disclosure. The isolated DC-DC converter 100 converts, with a transformer Tr, an input voltage Vin which is a direct-current voltage into an output voltage Vout which is a direct-current voltage while being isolated.

The isolated DC-DC converter 100 includes a semiconductor device 1, and an input resistor R1, an input capacitor C1, a power supply capacitor C2, diodes D1 and D2, an output capacitor Co and the transformer Tr which are provided discretely outside the semiconductor device 1. A rectifier smoothing circuit is formed with the diode D1 and the output capacitor Co.

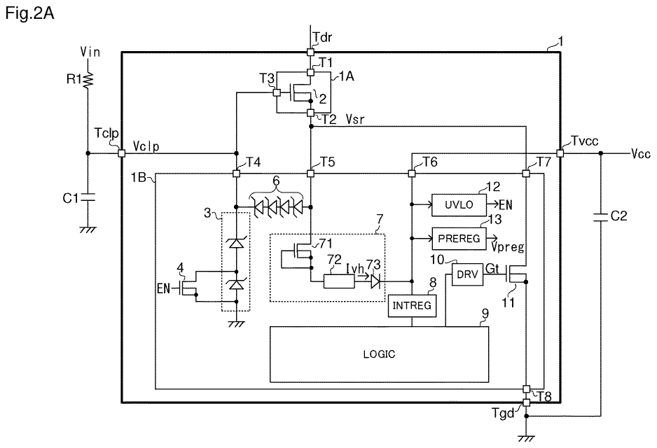

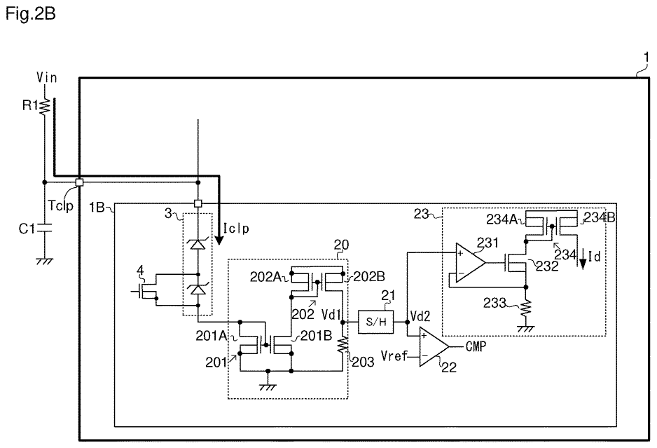

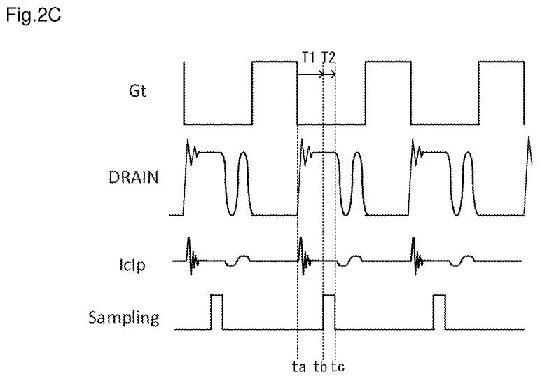

The semiconductor device 1 is a power supply IC (integrated circuit) which is packaged by integrating an internal configuration shown in FIG. 2A which will be described later. The semiconductor device 1 includes, as external terminals for establishing electrical connection to the outside, a clamp terminal Tclp, an EO terminal Teo, an EMI reduction terminal Temi, a drain terminal Tdr, a source terminal Tsr, a ground terminal Tgd, a power supply terminal Tvcc and a sense terminal Tvs.

The transformer Tr includes a primary winding w1, a secondary winding w2 and an auxiliary winding w3. The application end of the input voltage Vin is connected to one end of the primary winding w1. The other end of the primary winding w1 is connected to the drain terminal Tdr. One end of the secondary winding w2 is connected to the anode of the diode D1. The cathode of the diode D1 is connected to one end of the output capacitor Co. The other end of the output capacitor Co is connected to the other end of the secondary winding w2. The output voltage Vout is generated across the output capacitor Co.

One end of the auxiliary winding w3 is connected to the anode of the diode D2. The cathode of the diode D2 is connected to one end of the power supply capacitor C2, and is also connected to the power supply terminal Tvcc. The other end of the auxiliary winding w3 and the other end of the power supply capacitor C2 are connected to the application end of a ground potential.

The input resistor R1 and the input capacitor C1 will be described later.

### <Internal Configuration of Semiconductor Device>

FIG. 2A is a diagram showing the internal configuration of the semiconductor device 1. FIG. 2A shows only the characteristic configuration of the present disclosure inside the semiconductor device 1, and omits the other internal configurations.

As shown in FIG. 2A, the semiconductor device 1 includes a chip 1A and a chip 1B. In other words, the semiconductor device 1 has a multi-chip configuration.

The chip 1A includes a first element 2 which is integrated. The first element (first transistor) 2 is formed with an enhancement type N-channel MOSFET (metal-oxide-semiconductor field-effect transistor). The chip 1A includes electrodes T1 to T3. The drain of the first element 2 is connected to the drain terminal Tdr via the electrode T1.

The application end of the input voltage Vin is connected to one end of the input resistor R1. The other end of the input resistor R1 and one end of the input capacitor C1 are connected to the clamp terminal Tclp. The other end of the input capacitor C1 is connected to the application end of the ground potential. Although the input capacitor C1 is provided to stabilize a terminal voltage Vclp at the clamp terminal Tclp, the input capacitor C1 is not essential.

The clamp terminal Tclp is connected to the gate of the first element 2 via the electrode T3. In this way, the terminal voltage Vclp is connected to the gate of the first element 2.

The chip 1B includes a clamping circuit 3, a switch 4, a protection unit 6, a current control circuit 7, an internal regulator 8, a logic unit 9, a drive unit 10, a second element (second transistor) 11, a UVLO (Under Voltage Lock Out) unit 12 and a pre-regulator 13 which are integrated. The chip 1B also includes electrodes T4 to T8.

The clamping circuit 3 is a circuit for clamping the terminal voltage Vclp, and is configured by connecting Zener diodes in series. The cathode of the Zener diode on the highest potential side is connected to the clamp terminal Tclp via the electrode T4, and the anode of the Zener diode on the lowest potential side is connected to the application end of the ground potential. The number of Zener diodes which form the clamping circuit 3 is not particularly limited as long as the number is one or more.

The switch 4 is connected between both ends of a part of the Zener diodes which form the clamping circuit 3. The on and off of the switch 4 is controlled by an enable signal EN. When the switch 4 is turned on, the part of the Zener diodes is bypassed, and thus a clamp voltage provided by the clamping circuit 3 is lowered.

The source of the first element 2 is connected to the electrode T5 via the electrode T2. The protection unit 6 is connected between one ends of the electrodes T5 and T4. The protection unit 6 is configured by connecting Zener diodes in series. The anode of the Zener diodes is connected to the electrode T5, and the cathode thereof is connected to the electrode T4. By voltage clamping provided by the protection unit 6, protection is performed for the Vgs (gate-source voltage) withstand voltage of the first element 2.

The current control circuit 7 is connected between the electrodes T5 and T6. The electrode T6 is connected to the one end of the power supply capacitor C2 via the power supply terminal Tvcc. The current control circuit 7 controls a VH charging current Ivh which is passed for charging the power supply capacitor C2 at startup when the application of the input voltage Vin is started. The specific configuration of the current control circuit 7 will be described later.

The internal regulator 8 is a power supply circuit which subjects a power supply voltage Vcc applied to the power supply terminal Tvcc to DC-DC conversion, and supplies the converted voltage to the logic unit 9.

The second element 11 is formed with an N-channel MOSFET, and functions as a switching element. The drain of the second element 11 is connected to the source of the first element 2 via the electrodes T7 and T2. The source of the second element 11 is connected to the ground terminal Tgd via the electrode T8. The ground terminal Tgd is connected to the application end of the ground potential.

The drive unit 10 drives the second element 11 by applying a gate voltage Gt to the gate of the second element 11 under the control of the logic unit 9. The gate voltage Gt is switched high, and thus the second element 11 is turned on whereas the gate voltage Gt is switched low, and thus the second element 11 is turned off. The second element 11 is subjected to switching drive, and thus energy is transmitted from the primary side to the secondary side of the transformer Tr.

The UVLO unit 12 monitors the power supply voltage Vcc to detect whether the power supply voltage Vcc is in a UVLO state or in a UVLO release state. When the power supply voltage Vcc is equal to or less than a predetermined UVLO release voltage, the power supply voltage Vcc is in the UVLO state whereas when the power supply voltage Vcc exceeds the UVLO release voltage, the power supply voltage Vcc is in the UVLO release state. The UVLO unit 12 outputs the enable signal EN which indicates whether the power supply voltage Vcc is in the UVLO state.

When the power supply voltage Vcc which is input is lower than a predetermined voltage, the pre-regulator 13 outputs the power supply voltage Vcc as a regulator output Vpreg whereas when the power supply voltage Vcc which is input is equal to or greater than the predetermined voltage, the pre-regulator 13 outputs the predetermined voltage as the regulator output Vpreg. The regulator output Vpreg is used for control in the current control circuit 7 as will be described later.

### <Configuration of Current Control Circuit>

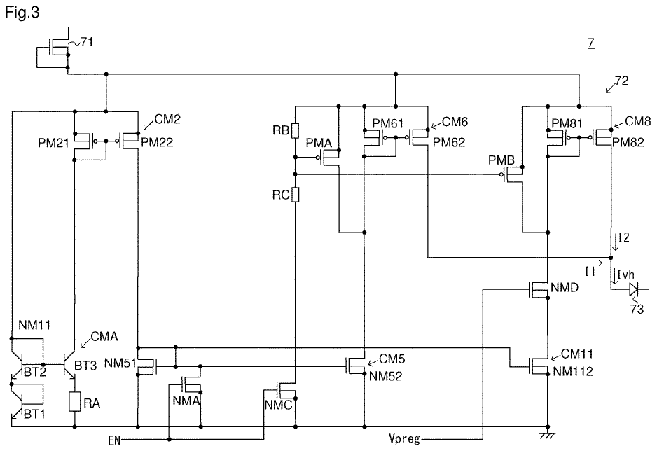

FIG. 3 is a diagram showing an example of the configuration of the current control circuit 7. The current control circuit 7 includes a depletion MOS transistor 71, a constant current circuit 72 and a backflow prevention diode 73.

The depletion MOS transistor 71 is formed with a depletion type N-channel MOS transistor. The drain of the depletion MOS transistor 71 is connected to the electrode T5 (FIG. 2A). The gate and source of the depletion MOS transistor 71 are shorted-circuited. In this way, the depletion MOS transistor 71 is operated as a constant current source.

The constant current circuit 72 is connected between the source of the depletion MOS transistor 71 and the anode of the backflow prevention diode 73. The constant current circuit 72 includes an NPN transistor (bipolar transistor) BT1, resistors RA to RC, a current mirror CMA, current mirrors CM2, CM5, CM6, CM8 and CM11, NMOS transistors NMA, NMC and NMD and PMOS transistors PMA and PMB. The NMOS transistor is an N-channel MOSFET, and the PMOS transistor is a P-channel MOSFET.

The emitter of the NPN transistor BT1 is connected to the application end of the ground potential. The base and collector of the NPN transistor BT1 are short-circuited. The current mirror CMA includes NPN transistors BT2 and BT3. The collector of the NPN transistor BT1 is connected to the emitter of the NPN transistor BT2. The base and collector of the NPN transistor BT2 are short-circuited. The bases of the NPN transistors BT2 and BT3 are connected to each other. The emitter of the NPN transistor BT3 is connected to one end of the resistor RA. The other end of the resistor RA is connected to the application end of the ground potential. The collector of the NPN transistor BT2 is connected to the source of the depletion MOS transistor 71.

The current mirror CM2 includes PMOS transistors PM21 and PM22. The sources of the PMOS transistors PM21 and PM22 are connected to the source of the depletion MOS transistor 71. The gate and drain of the PMOS transistor PM21 is short-circuited. The gates of the PMOS transistors PM21 and PM22 are connected to each other. The drain of the PMOS transistor PM21 is connected to the collector of the NPN transistor BT3.

The current mirror CM5 includes NMOS transistors NM51 and NM52. The drain of the NMOS transistor NM51 is connected to the drain of the PMOS transistor PM22. The gate and drain of the NMOS transistor NM51 are short-circuited. The gates of the NMOS transistors NM51 and NM52 are connected to each other. The source of the NMOS transistor NM51 is connected to the application end of the ground potential.

The source of the NMOS transistor NM52 is connected to the application end of the ground potential.

The current mirror CM6 includes PMOS transistors PM61 and PM62. The sources of the PMOS transistors PM61 and PM62 are connected to the source of the depletion MOS transistor 71. The gate and drain of the PMOS transistor PM61 are short-circuited. The gates of the PMOS transistors PM61 and PM62 are connected to each other. The drain of the PMOS transistor PM61 is connected to the drain of the NMOS transistor NM52.

The current mirror CM8 includes PMOS transistors PM81 and PM82. The sources of the PMOS transistors PM81 and PM82 are connected to the source of the depletion MOS transistor 71. The gate and drain of the PMOS transistor PM81 are short-circuited. The gates of the PMOS transistors PM81 and PM82 are connected to each other. The drain of the PMOS transistor PM82 and the drain of the PMOS transistor PM62 are connected to the anode of the backflow prevention diode 73.

The drain of the NMOS transistor NMA is connected to the gates of the NMOS transistors NM51 and NM52. The source of the NMOS transistor NMA is connected to the application end of the ground potential.

The source of the NMOS transistor NMC is connected to the application end of the ground potential. The resistors RB and RC are connected in series between the source of the depletion MOS transistor 71 and the drain of the NMOS transistor NMC. The gates of the PMOS transistors PMA and PMB are connected to the node to which the resistors RB and RC are connected.

The source of the PMOS transistor PMA is connected to the source of the PMOS transistor PM61. The drain of the PMOS transistor PMA is connected to the drain of the PMOS transistor PM61. The source of the PMOS transistor PMB is connected to the source of the PMOS transistor PM81. The drain of the PMOS transistor PMB is connected to the drain of the PMOS transistor PM81.

The enable signal EN is applied to the gates of the NMOS transistors NMA and NMC.

The current mirror CM11 includes the NMOS transistor NM51 and an NMOS transistor NM112. In other words, the current mirrors CM11 and CM5 share the NMOS transistor NM51.

The drain of the NMOS transistor NMD is connected to the drain of the PMOS transistor PM81. The source of the NMOS transistor NMD is connected to the drain of the NMOS transistor NM112. The source of the NMOS transistor NM112 is connected to the application end of the ground potential. The regulator output Vpreg is applied to the gate of the NMOS transistor NMD.

In the constant current circuit 72 configured as described above, since a bandgap current source is formed with the NPN transistors BT1, BT2 and BT3 and the resistor RA, and VF (forward voltage) caused by the NPN transistors BT1 and BT2 is equal to VF+RA×Iout (Iout: output current flowing through the resistor RA) caused by the NPN transistor BT3, the temperature characteristic of the forward voltage VF and the temperature characteristic of the resistor RA are combined to make the temperature characteristic of the output current flat. The amount of constant current provided by the constant current circuit 72 is adjusted by the current mirror. Since the semiconductor element has excellent pairing properties, the accuracy of the absolute value of the constant current is enhanced.

### <Operation of Semiconductor Device>

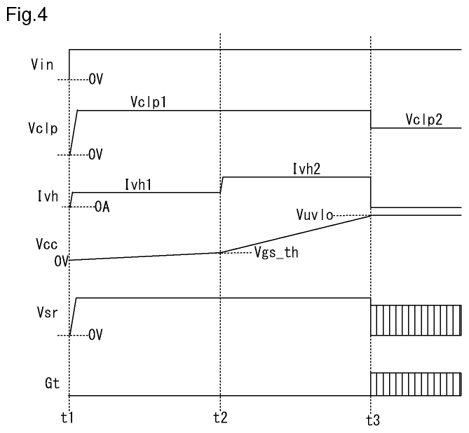

The operation of the semiconductor device 1 configured as described above will then be described with reference to a timing chart shown in FIG. 4. FIG. 4 shows, sequentially from an upper stage, examples of the waveforms of the input voltage Vin, the terminal voltage Vclp at the clamp terminal Tclp, the charging current Ivh generated by the current control circuit 7, the power supply voltage Vcc, the source voltage Vsr of the first element 2 and the gate voltage Gt.

When the application of the input voltage Vin is first started at a timing t1, a startup operation is started. Here, the terminal voltage Vclp immediately rises to a clamp voltage Vclp1 due to the charging of the input capacitor C1. The UVLO state is detected by the UVLO unit 12, and thus the enable signal EN is switched low, and the switch 4 is turned off. In this way, the clamping circuit 3 causes the terminal voltage Vclp to be the clamp voltage Vclp1. The clamp voltage Vclp1 is applied to the gate of the first element 2. The first element 2 is brought into a conductive state, and thus the source voltage Vsr is lower than the clamp voltage Vclp1 by the Vgs of the first element 2. For example, when it is assumed that clamp voltage Vclp1=30 V, and Vgs of first element 2=3 V, the source voltage Vsr is 27 V.

The source voltage Vsr is applied to the current control circuit 7, and thus the generation of the charging current Ivh is started. In the current control circuit 7 shown in FIG. 3, the enable signal EN is low. In this way, the NMOS transistor NMA is turned off, and the current mirror CM5 is enabled.

The NMOS transistor NMC is also turned off, the PMOS transistor PMA is turned off and thus the current mirror CM6 is enabled. On the other hand, the regulator output Vpreg is lower than the threshold value Vgs_th (for example, 2 V) of the Vgs of the NMOS transistor NMD, and thus the NMOS transistor NMD is turned off. In this way, the PMOS transistor PMB is off but the current mirror CM8 is disabled.

Hence, the constant current flowing through the resistor RA is mirrored by the current mirrors CM2, CM5 and CM6, and thus a current I1 which is output from the drain of the PMOS transistor PM62 is generated. A current I2 which is output from the drain of the PMOS transistor PM82 is not generated. Although the currents I1 and I2 are combined to generate the charging current Ivh, the current I2 is not generated, and thus the current I1 is output as the charging current Ivh. When the charging current Ivh here is assumed to be Ivh1, for example, Ivh1=480 μA.

The charging current Ivh (Ivh1) is supplied to the power supply capacitor C2, and thus the power supply capacitor C2 is charged, with the result that the power supply voltage Vcc is gradually increased.

Then, when at a timing t2, the power supply voltage Vcc exceeds the threshold value Vgs_th of the Vgs of the NMOS transistor NMD, the regulator output Vpreg exceeds the threshold value Vgs_th, and thus the NMOS transistor NMD is turned on (switched from off to on), with the result that the current mirror CM8 is enabled. In this way, a current flowing through the resistor RA is mirrored by the current mirrors CM2, CM11 and CM8, and thus the current I2 is generated. Hence, the current I2 is added to the current I1, and thus the charging current Ivh is output. When the charging current Ivh here is assumed to be Ivh2, for example, Ivh2=1.3 mA.

The reason why as described above, the charging current Ivh is first set to Ivh1 which is low and is then set to Ivh2 which is high is that if the power supply terminal Tvcc is subjected to a ground fault, the power supply voltage Vcc is fixed at 0 V, and thus a loss caused by the charging current Ivh is problematic. In particular, when the input voltage Vin is so high as to be, for example, 1000 V, the loss is particularly problematic. Then, when the power supply voltage Vcc is somewhat increased, no ground fault occurs, and thus the charging current Ivh is switched to a high value so that a startup time is shortened.

When the power supply voltage Vcc is further increased by the charging of the charging current Ivh (Ivh2), and thus the power supply voltage Vcc reaches a UVLO release voltage Vuvlo, the UVLO unit 12 detects UVLO release. Here, the enable signal EN is switched from low to high, the NMOS transistor NMA is turned on and thus the current mirror CM5 is disabled. The NMOS transistor NMC is also turned on, and thus the PMOS transistors PMA and PMB are turned on, with the result that the current mirrors CM6 and CM8 are disabled. In this way, the currents I1 and I2 are not generated, and thus the output of the charging current Ivh is stopped. Here, in the current control circuit 7, a current flowing through the NPN transistor BT1 and the resistor RA serves as a standby current, and thus it is possible to significantly suppress the standby current.

Since the enable signal EN is high, the switch 4 is turned on, and thus the terminal voltage Vclp becomes a clamp voltage Vclp2 which is lower than the clamp voltage Vclp1. For example, when it is assumed that Vclp1=30 V, Vclp2=20V. On the other hand, due to the UVLO release, switching drive on the second element 11 is started by the drive unit 10 under the control of the logic unit 9 (the gate voltage Gt in FIG. 4). In this way, the startup operation is completed, and power conversion via the transformer Tr is started.

The clamp voltage is switched by the switch 4 in the clamping circuit 3 because a voltage value which needs to be applied to the gate of the first element 2 differs between the startup and the time during which switching is performed. Specifically, at startup, when the power supply voltage Vcc reaches the UVLO release voltage Vuvlo, the power supply voltage Vcc, the forward voltage of the backflow prevention diode 73, the Vds (drain-source voltage) of the PMOS transistor PM62 or PM82, the Vds of the depletion MOS transistor 71 and the Vgs of the first element 2 are added together to be, for example, 23 V, and a voltage value (for example, 30 V) with a margin is set to the clamp voltage Vclp1. On the other hand, during switching, when the second element 11 is in an on state, source voltage Vsr=0 V, and with consideration given to the Vgs withstand voltage (for example, 26 V) of the first element 2, a voltage value (for example, 20 V) which can bring the first element 2 into a fully on state is set to the clamp voltage Vclp2.

In the embodiment as described above, the first element 2 can be used both at startup and during switching, and it is not necessary to additionally provide an element for startup, with the result that it is possible to reduce the number of components. A semiconductor material used for the first element 2 can be changed depending on the value of the input voltage Vin. For example, in the case of a high voltage such as input voltage Vin=1000 V, as the semiconductor material, SiC, GaN or the like is used whereas in the case of a voltage such as input voltage Vin=400 V, as the semiconductor material, Si or the like can be used. It is only necessary to provide the input resistor R1 and the input capacitor C1 outside the clamp terminal Tclp, and thus as compared with a case where a startup circuit for stepping down the input voltage is provided outside the semiconductor device, it is possible to reduce the number of components and to reduce the area of a substrate on which the semiconductor device is mounted.

In the current control circuit 7 (FIG. 3), the depletion MOS transistor 71 and the constant current circuit 72 are used. Since the depletion MOS transistor 71 tends to have a large variation in constant current characteristics, the gate width and the gate length of the depletion MOS transistor 71 are adjusted, and thus a sufficient current capacity (for example, 5 mA) is provided whereas the accuracy of the constant current is enhanced by the constant current circuit 72. In this way, the constant current accuracy of the charging current Ivh is enhanced, and a variation in the startup time is suppressed. A configuration may be adopted in which the depletion MOS transistor is not provided. However, the depletion MOS transistor is provided, and thus it is possible to suppress an unstable current during switching. Only the depletion MOS transistor may be provided and used as the constant current source.

### <Variation>

FIG. 2B is a diagram showing a variation of the configuration of the chip 1B in the semiconductor device 1. The configuration shown in FIG. 2B differs from that shown in FIG. 2A in the connection to the anode of the Zener diode on the lowest potential side in the clamping circuit 3. The configuration of the chip 1B which is not shown in FIG. 2B is the same as the configuration shown in FIG. 2A.

The chip 1B in FIG. 2B includes an I-V (current·voltage) conversion unit 20, a sample and hold circuit 21, a comparator 22 and a V-I (voltage·current) conversion unit 23.

The I-V conversion unit 20 includes current mirrors 201 and 202 and a conversion resistor 203. The current mirror 201 includes NMOS transistors 201A and 201B. The drain of the NMOS transistor 201A is connected to the anode of the Zener diode on the lowest potential side in the clamping circuit 3. The gate and drain of the NMOS transistor 201A are short-circuited. The gates of the NMOS transistors 201A and 201B are connected to each other. The sources of the NMOS transistors 201A and 201B are connected to the application end of the ground potential. The current mirror 202 includes PMOS transistors 202A and 202B. The drain of the PMOS transistor 202A is connected to the drain of the NMOS transistor 201B. The gate and drain of the PMOS transistor 202A are short-circuited. The gates of the PMOS transistors 202A and 202B are connected to each other. The drain of the PMOS transistor 202B is connected to one end of the conversion resistor 203. The other end of the conversion resistor 203 is connected to the application end of the ground potential.

In the configuration of the I-V conversion unit 20 as described above, a current Iclp which flows from the application end of the input voltage Vin through the input resistor R1, the clamp terminal Tclp and the clamping circuit 3 is sequentially mirrored by the current mirrors 201 and 202, and is converted by the conversion resistor 203 into a detection voltage Vd1.

The sample and hold circuit 21 samples and holds the detection voltage Vd1. Since the clamp terminal Tclp is a high-impedance terminal, the sample and hold circuit 21 is provided to suppress the influence of switching noise caused by the switching of the second element 11 (not shown in FIG. 2B).

FIG. 2C is a waveform diagram for illustrating the sampling timing of the sample and hold circuit 21. FIG. 2C shows, sequentially from an upper stage, the gate voltage Gt, the drain voltage DRAIN of the second element 11, the current Iclp and a sampling state.

At a timing ta when the gate voltage Gt is switched from high to low, the second element 11 is turned off, and thus the drain voltage DRAIN rises. Immediately after the rise, fluctuations occur in the drain voltage DRAIN, and fluctuations also occur in the current Iclp. At a timing tb when a predetermined time T1 has elapsed from the timing ta, the fluctuations in the drain voltage DRAIN and the current Iclp have subsided, and here, sampling is started (that is, holding is released). Then, sampling is performed until a timing tc when a predetermined time T2 has elapsed, sampling is completed at the timing tc, and holding is performed. During a period from the timing tb to the timing tc, the drain voltage DRAIN and the current Iclp are stable, and sampling can be performed in a state where the influence of switching noise is suppressed.

As a result of sampling and holding performed by the sample and hold circuit 21, a detection voltage Vd2 is output. The detection voltage Vd2 is applied to the first input end of the comparator 22. A reference voltage Vref is applied to the second input end of the comparator 22. The comparator 22 compares the detection voltage Vd2 with the reference voltage Vref to output a comparison output CMP.

Here, the current Iclp is represented by an equation below.

Iclp=(Vin −(Vz+Vgs))/R1

where Vz is the Zener voltage of the clamping circuit 3, and Vgs is the Vgs of the NMOS transistor 201A.

When a voltage at the clamp terminal Tclp is normal, the current Iclp represented by the above equation is converted by the I-V conversion unit 20 into the detection voltage Vd1, and the detection voltage Vd2 caused by the sample and hold circuit 21 is applied to the comparator 22. In this case, the detection voltage Vd2 is equal to or greater than the reference voltage Vref, and the comparison output CMP is the corresponding logic level. The temperature characteristic of Vz+Vgs in the above equation is adjusted, and thus the temperature characteristic of Iclp is made flat.

On the other hand, when the voltage at the clamp terminal Tclp is abnormally lowered, the current Iclp is increased, and thus the detection voltage Vd2 is increased beyond the reference voltage Vref. The comparison output CMP has the corresponding logic level, and thus an abnormal state can be detected.

The V-I conversion unit 23 includes an error amplifier 231, an NMOS transistor 232, a resistor 233 and a current mirror 234. The non-inverting input terminal of the error amplifier 231 is connected to the application end of the detection voltage Vd2. The output end of the error amplifier 231 is connected to the gate of the NMOS transistor 232. The source of the NMOS transistor 232 is connected to the inverting input terminal of the error amplifier 231 and one end of the resistor 233. The other end of the resistor 233 is connected to the application end of the ground potential. The current mirror 234 includes PMOS transistors 234A and 234B. The drain of the PMOS transistor 234A is connected to the drain of the NMOS transistor 232. The gate and drain of the PMOS transistor 234A are short-circuited. The gates of the PMOS transistors 234A and 234B are connected to each other. The sources of the PMOS transistors 234A and 234B are connected to each other.

In the configuration of the V-I conversion unit 23 as described above, the detection voltage Vd2 is generated at the one end of the resistor 233. In this way, a current corresponding to the detection voltage Vd2 flows through the resistor 233, and is mirrored by the current mirror 234 to turn into a detection current Id. As in the above equation, the current Iclp depends on the input voltage Vin, and thus the input voltage Vin can be detected by the detection current Id. The detection current Id is utilized to control an OCP (overcurrent protection) voltage or the like.

In the configuration in FIG. 2B as described above, the clamping circuit 3 can also be used to detect the current Iclp.

### <Input Voltage Detection>

### First Embodiment

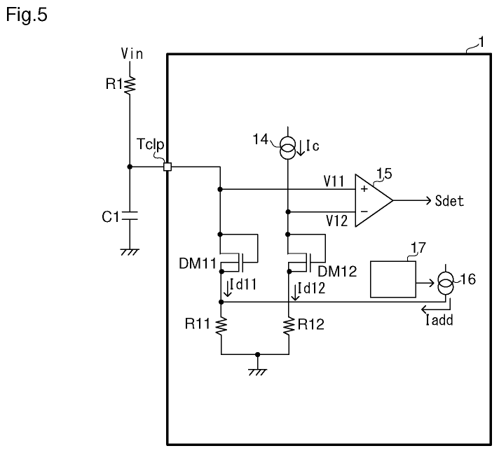

An input voltage detection function included in the semiconductor device 1 according to the present embodiment will then be described. FIG. 5 is a diagram showing a configuration related to input voltage detection in the semiconductor device 1 according to the first embodiment. The semiconductor device 1 includes, as a configuration for detecting the input voltage Vin, a MOS transistor DM11, a MOS transistor DM12, a resistor R11, a resistor R12, a constant current source 14 and a comparator 15.

Each of the MOS transistors DM11 and DM12 is formed with a depletion type N-channel MOSFET. The clamp terminal Tclp is connected to the drain of the MOS transistor DM11. The drain and gate of the MOS transistor DM11 are short-circuited. The source of the MOS transistor DM11 is connected to one end of the resistor R11. The other end of the resistor R11 is connected to the application end of the ground potential.

The constant current source 14 is connected to the drain of the MOS transistor DM12. The drain and gate of the MOS transistor DM12 are short-circuited. The source of the MOS transistor DM12 is connected to one end of the resistor R12. The other end of the resistor R12 is connected to the application end of the ground potential.

The drain voltage V11 of the MOS transistor DM11 is input to the non-inverting input terminal (+) of the comparator 15. The drain voltage V12 of the MOS transistor DM12 is input to the inverting input terminal (−) of the comparator 15. The comparator 15 compares the drain voltages V11 and V12 to output a detection signal Sdet. When V11>V12, the detection signal Sdet is high whereas when V11≤V12, the detection signal Sdet is low.

Here, a drain current Id11 flows through the MOS transistor DM11. Id11 is represented by equation (1) below.

Id1=(Vin−Vgs11)/(R1+R11) (1)

where Vgs11 is the Vgs of the MOS transistor DM11.

In equation (1) described above, since R1>R11 (for example, R1=10 MΩ, and R11=several tens of ohms), equation (2) is obtained.

Id11=(Vin−Vgs11)/R1 (2)

The drain voltages V11 and V12 are represented by equations (3) and (4) below.

V11=Id11×R11+Vgs11 (3)

V12=Id12×R12+Vgs12 (4)

where Id12 is a drain current flowing through the MOS transistor DM12, and Vgs12 is the Vgs of the MOS transistor DM12.

Here, Vgs11 and Vgs12 are represented by equations (5) and (6) below.

Vgs11=√((2×Id11/K×W/L))+VT (5)

Vgs12=√((2×Id12/K×W/L))+VT (6)

where K=μ×Cox, W is a gate width, L is a gate length, VT is a threshold voltage, p is an electron mobility and Cox is a capacitance per unit area of a MOS capacitor.

In the MOS transistors DM11 and DM12, K, W, L and VT are set to the same values. The relative error of the value of W/L caused by product variations between the MOS transistors DM11 and DM12 inside the semiconductor device 1 is small (pairing properties of DM11 and DM12). Hence, when Id11=Id12, Vgs11=Vgs12, and when R11 is set equal to R12, V11=V12.

Since Id12=Ic (constant current provided by the constant current source 14), equations (2) and (5) described above are used, and thus the following equation holds true.

Ic=(Vin−(√((2×Ic/K×W/L))+VT))/R1 (7)

When the detection threshold value of the input voltage Vin is assumed to be Vth_det, Ic is set such that the following equation is satisfied.

Ic=(Vth_det−(√((2×Ic/K×W/L))+VT))/R1 (8)

Then, when Vin>Vth_det, Id11>Id12, and thus V11>V12. On the other hand, when Vin≤Vth_det, Id11≤Id12, and thus V11≤V12. Hence, the input voltage Vin can be detected by the level of the detection signal Sdet which is the output of the comparator 15.

For example, when Vth_det is set equal to 50 V, it can be detected that Vin is equal to or less than 50 V, and thus a brownout occurs. By the pairing properties of the MOS transistors DM11 and DM12, it is possible to suppress a change in the detection threshold value Vth_det caused by the change of the temperature.

The MOS transistors DM11 and DM12 are not limited to the depletion type N-channel MOSFETs, and may be formed with enhancement type N-channel MOSFETs.

As shown in FIG. 5, the semiconductor device 1 includes a current addition unit 16 and a timing control unit 17. The current addition unit 16 is connected to the source of the MOS transistor DM11. The timing control unit 17 uses the current addition unit 16 to control the timing at which a current Iadd is added to the drain current Id11.

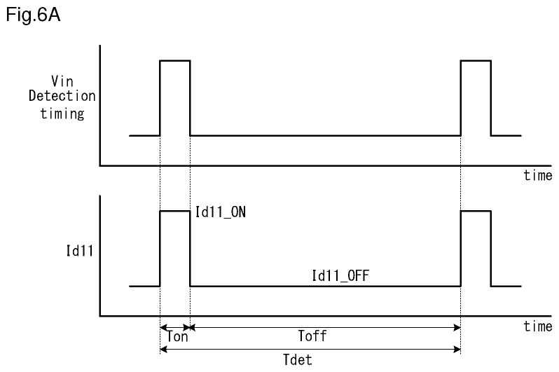

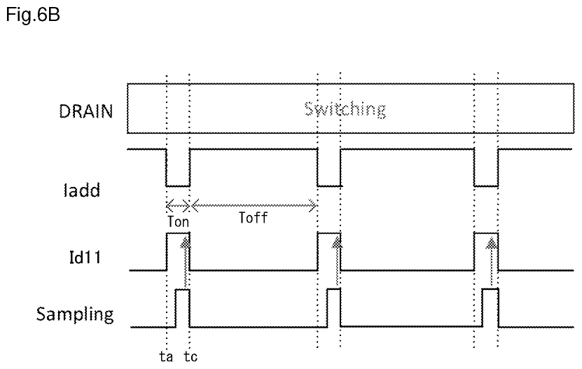

FIG. 6A is a timing chart schematically showing the detection timing (upper stage) of the input voltage Vin and the drain current Id11 (lower stage). In FIG. 6A, the period during which the detection timing of the input voltage Vin is high is a detection-on period Ton during which the input voltage Vin is detected, and the period during which the detection timing of the input voltage Vin is low is a detection-off period Toff during which the detection of the input voltage Vin is stopped. Ton+Toff=Tdet is a detection period.

The timing control unit 17 does not cause the current addition unit 16 to add the current Iadd during the detection-on period Ton, and causes the current addition unit 16 to add the current Iadd during the detection-off period Toff. The current Iadd is added, and thus the source voltage of the MOS transistor DM11 is increased, and the Vgs of the MOS transistor DM11 is decreased, with the result that the drain current Id11 is reduced. When it is assumed that the drain current during the detection-on period Ton is Id11=Id11_ON, and the drain current during the detection-off period Toff is Id11=Id11_OFF, Id1_ON>Id11_OFF.

A duty cycle during the detection-on period Ton is controlled as (Ton/Tdet)×100%. For example, when Vin=1000 V, Id11_ON=20 μA, Id11_OFF=1 μA and duty cycle=10%, the average current of Id11 is 20×0.1+1×0.9=2.9 μA. Hence, as compared with a case where duty cycle=100%, it is possible to reduce a loss of 1000 V×20 μA=20 mW to a loss of 1000 V×2.9 μA=2.9 mW. In particular, when the input voltage Vin is a high voltage as described above, the effect of reducing the loss is enhanced.

FIG. 6B is a timing chart related to timing control performed by the timing control unit 17. FIG. 6B shows, sequentially from an upper stage, the drain voltage DRAIN of the second element 11, the current Iadd, the drain current Id11 and a sampling state provided by a sample and hold circuit 21C (FIG. 2B). The drain voltage DRAIN schematically shows the waveform of the second element 11 in a switching state. A timing ta shown in FIG. 6B is the same as the timing ta in FIG. 2C, and is the timing at which the second element 11 is turned off. At the timing ta, the current Iadd is turned off. In this way, the drain current Id11 is increased. A timing tc after the timing ta in FIG. 6B is the same as the timing tc in FIG. 2C, and is the timing at which sampling is completed. At the timing tc, the current Iadd is generated, and the drain current Id11 is reduced. Thereafter, at the timing ta, the current Iadd is turned off again. A period between the timing ta and the timing tc is the detection-on period Ton, and a period between the timing tc and the subsequent timing ta is the detection-off period Toff.

### Second Embodiment

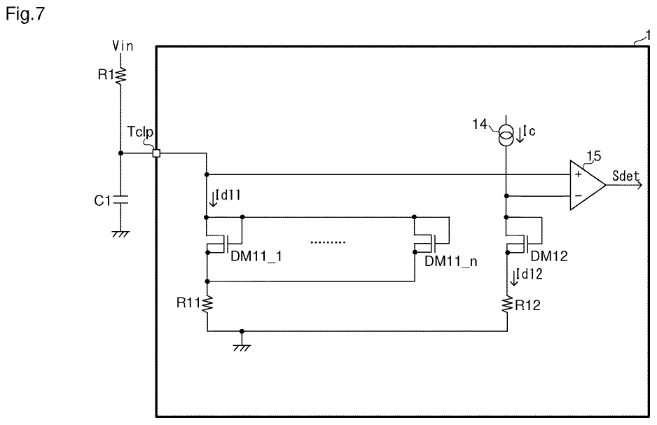

FIG. 7 is a diagram showing a configuration related to input voltage detection in a semiconductor device 1 according to a second embodiment. The second embodiment differs from the first embodiment in that MOS transistors DM11_1 to DM11_n (n is an integer of 2 or more) are connected in parallel. In each of the MOS transistors DM11_1 to DM11_n, K, W, L and VT are set to the same values as in the MOS transistor DM12. It can also be considered that the MOS transistors DM11_1 to DM11_n form one MOS transistor DM11 having a gate width of (n×W).

When Ic (the current value of the constant current source 14) serving as a drain current flows through each of the MOS transistors DM11_1 to DM11_n, that is, when Id11=n×Ic, equation (9) holds true.

V11=n×Ic×R11+Vgs11 (9)

On the other hand, equation (10) holds true.

V12=Ic×R12+Vgs12 (10)

Since Vgs11=√(2×n×Ic/(K×n×W/L))+VT (11), Vgs11=Vgs12, and when R11 is set equal to R12×(1/n), V11=V12.

Hence, a value obtained by multiplying Ic which satisfies equation (8) in the first embodiment by (1/n) is set to the setting value of Ic, and thus the value of Ic can be set lower.

Although in the configuration shown in FIG. 7, n MOS transistors DM11 are connected in parallel, and one MOS transistor DM12 is provided, m MOS transistors DM12 may be connected in parallel. Here, m is an integer which is equal to or greater than 2, and m<n is satisfied. In this case, it is assumed that R11=R12×(m/n).

Furthermore, the ratio of the gate width W of the MOS transistor DM11 (one MOSFET or a plurality of MOSFETs connected in parallel) to the gate width W of the MOS transistor DM12 (one MOSFET or a plurality of MOSFETs connected in parallel) may be set to k:1 (k>1). In this case, it is assumed that R11=R12×(1/k). In the embodiment described previously, this case corresponds to the case where k=n or the case where k=n/m.

### Third Embodiment

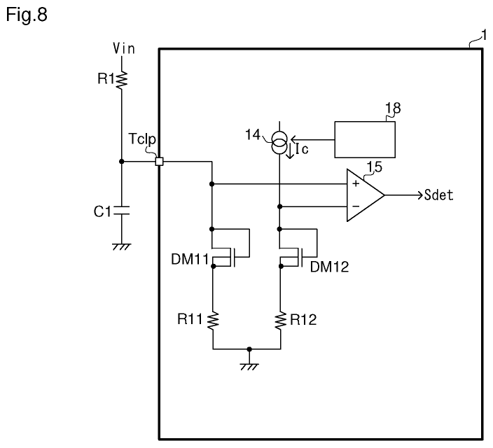

FIG. 8 is a diagram showing a configuration related to input voltage detection in a semiconductor device 1 according to a third embodiment. The third embodiment differs from the first embodiment in that a setting unit 18 is provided in the semiconductor device 1. The value of a constant current Ic provided by the constant current source 14 can be variably set by the setting unit 18. For example, when the setting unit 18 is formed with an EEPROM, the value of the constant current Ic is set according to setting information stored in the EEPROM. The setting unit 18 may include, for example, a blowable fuse, and may perform the setting by blowing the fuse.

In the embodiment as described above, the value of the constant current Ic can be variably set, and thus the detection threshold value Vth_det for detecting the input voltage Vin can be variably set.

### Fourth Embodiment

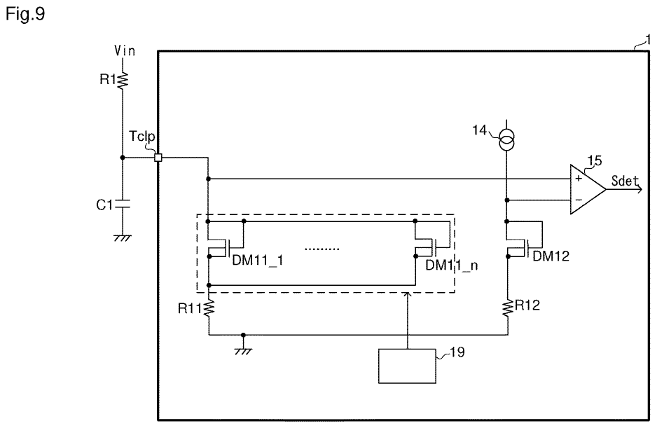

FIG. 9 is a diagram showing a configuration related to input voltage detection in a semiconductor device 1 according to a fourth embodiment. The fourth embodiment differs from the second embodiment in that a setting unit 19 is provided. Among MOS transistors DM11_1 to DM11_n, the number of MOS transistors DM11 to be enabled can be variably set by the setting unit 19. As with the setting unit 18 in the third embodiment, the setting unit 19 is formed with, for example, an EEPROM or a fuse.

In the embodiment as described above, the detection threshold value Vth_det for detecting the input voltage Vin can be variably set. As described in the second embodiment, when the m MOS transistors DM12 are connected in parallel, the setting unit 19 may variably set the number of MOSFETs to be enabled in at least either of the n MOS transistors DM11 and the m MOS transistors DM12.

Furthermore, as described in the second embodiment, when the ratio of the gate width W of the MOS transistor DM11 to the gate width W of the MOS transistor DM12 is set to k:1, the value of k may be variably set by the setting unit 19. This includes the embodiment in which the number of MOS transistors to be enabled is variably set as described above.

### Fifth Embodiment

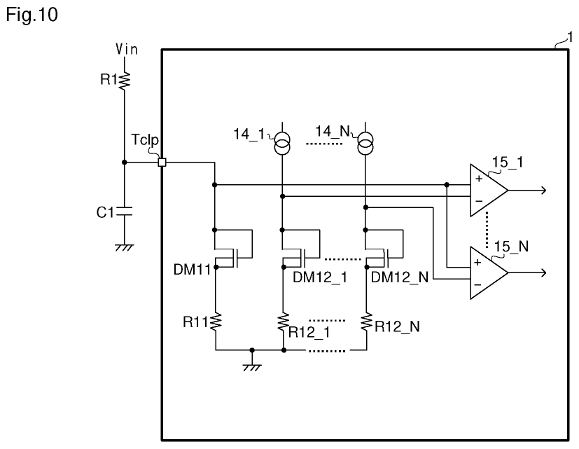

FIG. 10 is a diagram showing a configuration related to input voltage detection in a semiconductor device 1 according to a fifth embodiment. In the fifth embodiment, the semiconductor device 1 includes MOS transistors DM12_1 to DM12_N, resistors R12_1 to R12_N, constant current sources 14_1 to 14_N and comparators 15_1 to 15_N (where N is an integer of 2 or more).

In the configuration as described above, the values of constant currents provided by the constant current sources 14_1 to 14_N are set to different values, and thus a detection threshold value Vth_det for detecting Vin can be set to a different value by each of the comparators 15_1 to 15_N. The relative accuracy of the detection threshold values Vth_det is also high. The values of the constant currents provided by the constant current sources 14_1 to 14_N may be set to the same values, and the ratio of the gate width W of each of the MOS transistors DM12_1 to DM12_N and the gate width W of the MOS transistor DM11 may be set different.

### <Layout of External Terminals>

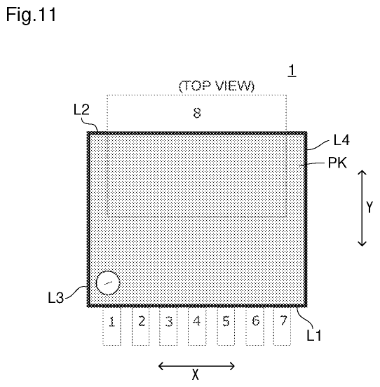

FIG. 11 is an example of a plan view when viewed from above the semiconductor device 1. As shown in FIG. 11, in the semiconductor device 1, external terminals (first to eighth pins) are connected to a package PK. In FIG. 11, a first direction (X) and a second direction (Y) orthogonal to each other are shown.

The package PK is rectangular in plan view to have sides L1 and L2 extending in the first direction and sides L3 and L4 extending in the second direction. The sides L1 and L2 are opposite each other in the second direction. The first to eighth pins are sequentially the power supply terminal Tvcc, the ground terminal Tgd, the EO terminal Teo, the sense terminal Tvs, the source terminal Tsr, the clamp terminal Tclp, the EMI reduction terminal Temi and the drain terminal Tdr, respectively.

The first to seventh pins are arranged along the side L1 of the package PK in plan view. The eight pin is arranged on the back surface of the package PK, and protrudes from the side L2 in the second direction in plan view. The eight pin is also used for heat dissipation.

### <AC-DC Converter>

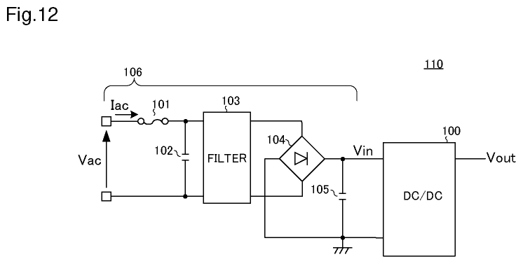

FIG. 12 is a diagram showing the configuration of an AC-DC converter 110 which uses the isolated DC-DC converter 100 according to the present embodiment. The AC-DC converter 110 includes an input circuit 106 and the isolated DC-DC converter 100. The input circuit 106 includes a fuse 101, a capacitor 102, a filter 103, a rectifier circuit 104 and a capacitor 105, and generates the input voltage Vin from an alternating-current voltage Vac.

The rectifier circuit 104 is, for example, a diode bridge. The alternating-current voltage Vac such as a commercial alternating-current voltage is supplied to the rectifier circuit 104 via the fuse 101, the capacitor 102 and the filter 103. The rectifier circuit 104 performs full-wave rectification on the alternating-current voltage Vac. The voltage subjected to the full-wave rectification is smoothed by the capacitor 105, and thus the input voltage Vin is generated. The input voltage Vin is input to the isolated DC-DC converter 100. The isolated DC-DC converter 100 steps down the input voltage Vin, and outputs the output voltage Vout. In the AC-DC converter as described above, the input voltage Vin is, for example, 400 V.

### <Vehicle>

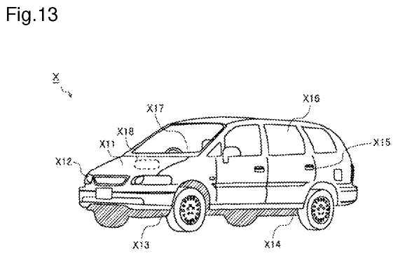

FIG. 13 is an external view showing an example of the configuration of a vehicle X. The vehicle X in the example of the configuration incorporates various electronic devices X11 to X18 which receive supply of power from an unillustrated battery to operate. The positions in which the electronic devices X11 to X18 shown in FIG. 13 are incorporated may be different from actual positions for convenience of illustration.

The electronic device X11 is an engine control unit which performs control related to an engine (such as injection control, electronic throttle control, idling control, oxygen sensor heater control and auto-cruise control).

The electronic device X12 is a lamp control unit which controls the turning on and off of an HID [high intensity discharge lamp], a DRL [daytime running lamp] and the like.

The electronic device X13 is a transmission control unit which performs control related to transmission.

The electronic device X14 is a body control unit which performs control related to the movement of the vehicle X (such as ABS [anti-lock brake system] control, EPS [electric power steering] control and electronic suspension control).

The electronic device X15 is a security control unit which performs drive control of door locks, burglar alarms and the like).

The electronic devices X16 are electronic devices which are installed in the vehicle X at the stage of shipments from a factory as standard equipment and manufacturer options such as wipers, power door mirrors, power windows, dampers (shock absorbers), a power sunroof and power seats.

The electronic devices X17 are electronic devices which are optionally installed in the vehicle X as user options such as an in-vehicle A/V (audio/visual) device, a car navigation system and an ETC (electronic toll collection system).

The electronic devices X18 are electronic devices, which includes a high-voltage-resistant motor, such as an in-vehicle blower, an oil pump, a water pump and a battery cooling fan.

The isolated DC-DC converter 100 including the semiconductor device 1 described above may receive supply of a high input voltage Vin such as 1000 V from the battery, and may be applied to any of the electronic devices X11 to X18.

### <Others>

In various technical features disclosed in the present specification, in addition to the embodiments described above, various changes can be added without departing from the spirit of the technical creation. In other words, it should be considered that the embodiments described above are illustrative in all respects, and not restrictive, and it is understood that the technical scope of the present disclosure is not limited to the embodiments described above and includes meanings equivalent to the scope of claims and all changes in the scope.

### <Additional Remarks>

As described above, a semiconductor device (1) according to an aspect of the present disclosure includes: a first external terminal (Tclp) configured such that an input voltage (Vin) is capable of being applied to a first end, and the first external terminal is connectable to a second end of an external resistor (R1); a first MOS transistor (DM11) of an N-channel configured such that a drain is connected to the first external terminal, and the drain and a gate are short-circuited; a first resistor (R11) configured such that a first end is connected to a source of the first MOS transistor; a constant current source (14); a second MOS transistor (DM12) of an N-channel configured such that a drain is connected to the constant current source, and the drain and a gate are short-circuited; a second resistor (R12) configured such that a first end is connected to a source of the second MOS transistor; and a comparator (15) configured such that a drain voltage (V11) of the first MOS transistor and a drain voltage (V12) of the second MOS transistor are input (first configuration).

In the configuration as described above, it is possible to effectively detect the input voltage.

In the first configuration described above, the semiconductor device (1) may further include: a current addition unit (16) configured to be connected to the source of the first MOS transistor, and to add a current (Iadd) to a drain current (Id11) flowing through the first MOS transistor; and a timing control unit (17) configured to control a duty cycle of the current addition unit by controlling an on and off of the addition of the current (second configuration).

In the first or second configuration described above, a ratio of a gate width of the first MOS transistor to a gate width of the second MOS transistor may be k:1 (k>1) (third configuration).

In the third configuration described above, the first MOS transistor may be configured by connecting n (n is an integer of 2 or more) first MOSFETs in parallel, and the second MOS transistor may be configured by one second MOSFET or by connecting m (m is an integer of 2 or more and m<n) second MOSFETs in parallel (fourth configuration).

In the third configuration described above, the semiconductor device (1) may further include: a first setting unit (19) configured to variably set a value of the k (fifth configuration).

In the fourth configuration described above, the semiconductor device (1) may further include: a first setting unit (19) configured to variably set a number of MOSFETs to be enabled in at least either of the n first MOSFETs and the m second MOSFETs (sixth configuration).

In any one of the first to sixth configurations described above, the semiconductor device (1) may further include: a second setting unit (18) configured to variably set a value of a constant current (Ic) provided by the constant current source (seventh configuration).

In any one of the first to seventh configurations described above, N (N is an integer of 2 or more) second MOS transistors each being the second MOS transistor, N second resistors each being the second resistor, N constant current sources each being the constant current source and N comparators each being the comparator may be provided (eighth configuration).

In any one of the first to eighth configurations described above, the first MOS transistor and the second MOS transistor may be depletion type MOS transistors (ninth configuration).

In any one of the first to ninth configurations described above, the semiconductor device (1) may further include: a clamping circuit (3) configured to clamp a voltage of the first external terminal; a first element (2) of an enhancement type configured such that a control end is connected to the first external terminal and including a first main electrode and a second main electrode; a drive unit (10); a second element (11) configured such that a first main electrode is connected to the second main electrode of the first element, and a control end is driven by the drive unit; and a current control circuit (7) configured to be connected between the second main electrode of the first element and a power supply capacitor (C2), at startup when the application of the input voltage is started, the power supply capacitor may be charged by a charging current (Ivh) output from the current control circuit, and when a power supply voltage is increased by the charging of the power supply capacitor to reach a UVLO release voltage, the current control circuit may stop generating the charging current, and the drive unit may start switching drive on the second element with the first element in a conductive state (tenth configuration).

An isolated DC-DC converter (100) according to an aspect of the present disclosure includes: the semiconductor device according to any one of the first to tenth configurations described above; a switching element (11) configured to be driven by the semiconductor device; a transformer including a primary winding (w1) connected between an application end of the input voltage and the switching element and a secondary winding (w2); and a rectifier smoothing circuit (D1, Co) configured to be connected to the secondary winding (eleventh configuration).

An AC-DC converter (110) according to an aspect of the present disclosure includes: the isolated DC-DC converter in the eleventh configuration; and an input circuit (106) configured to generate the input voltage from an alternating-current voltage (Vac) (twelfth configuration).

A vehicle (X) according to an aspect of the present disclosure includes: the isolated DC-DC converter in the eleventh configuration; and a battery configured to output the input voltage (thirteenth configuration).

What is claimed is:

1. A semiconductor device comprising:
a first external terminal configured such that
an input voltage is capable of being applied to a first end, and the first external terminal is connectable to a second end of an external resistor;
a first MOS transistor of an N-channel configured such that
a drain is connected to the first external terminal, and the drain and a gate are short-circuited;
a first resistor configured such that
a first end is connected to a source of the first MOS transistor;
a constant current source;
a second MOS transistor of an N-channel configured such that
a drain is connected to the constant current source, and the drain and a gate are short-circuited;
a second resistor configured such that
a first end is connected to a source of the second MOS transistor; and
a comparator configured such that
a drain voltage of the first MOS transistor and a drain voltage of the second MOS transistor are input.

2. The semiconductor device according to claim 1 further comprising:
a current addition unit configured
to be connected to the source of the first MOS transistor, and
to add a current to a drain current flowing through the first MOS transistor; and
a timing control unit configured
to control a duty cycle of the current addition unit by controlling an on and off of the addition of the current.

3. The semiconductor device according to claim 1,
wherein a ratio of a gate width of the first MOS transistor to a gate width of the second MOS transistor is k:1 (k>1).

4. The semiconductor device according to claim 3,
wherein the first MOS transistor is configured by connecting n (n is an integer of 2 or more) first MOSFETs in parallel, and
the second MOS transistor is configured by one second MOSFET or by connecting m (m is an integer of 2 or more and m<n) second MOSFETs in parallel.

5. The semiconductor device according to claim 3 further comprising:
a first setting unit configured to variably set a value of the k.

6. The semiconductor device according to claim 4 further comprising:
a first setting unit configured to variably set a number of MOSFETs to be enabled in at least either of the n first MOSFETs and the m second MOSFETs.

7. The semiconductor device according to claim 1 further comprising:
a second setting unit configured to variably set a value of a constant current provided by the constant current source.

8. The semiconductor device according to claim 1,
wherein N (N is an integer of 2 or more) second MOS transistors each being the second MOS transistor, N second resistors each being the second resistor, N constant current sources each being the constant current source and N comparators each being the comparator are provided.

9. The semiconductor device according to claim 1,
wherein the first MOS transistor and the second MOS transistor are depletion type MOS transistors.

10. The semiconductor device according to claim 1 further comprising:
a clamping circuit configured to clamp a voltage of the first external terminal;
a first element of an enhancement type
configured such that a control end is connected to the first external terminal and
including a first main electrode and a second main electrode;
a drive unit;
a second element configured such that
a first main electrode is connected to the second main electrode of the first element, and a control end is driven by the drive unit; and
a current control circuit configured to be connected between the second main electrode of the first element and a power supply capacitor,
wherein at startup when the application of the input voltage is started, the power supply capacitor is charged by a charging current output from the current control circuit, and
when a power supply voltage is increased by the charging of the power supply capacitor to reach a UVLO release voltage, the current control circuit stops generating the charging current, and the drive unit starts switching drive on the second element with the first element in a conductive state.

11. An isolated DC-DC converter comprising:
the semiconductor device according to claim 1;
a switching element configured to be driven by the semiconductor device;
a transformer including a primary winding connected between an application end of the input voltage and the switching element and a secondary winding; and
a rectifier smoothing circuit configured to be connected to the secondary winding.

12. An AC-DC converter comprising:
the isolated DC-DC converter according to claim 11; and
an input circuit configured to generate the input voltage from an alternating-current voltage.

13. A vehicle comprising:
the isolated DC-DC converter according to claim 11; and
a battery configured to output the input voltage.
